(19) United States
(12) Patent Application Publication
(10) Pub. No.: US 2026/0143635 A1
(43) Pub. Date: May 21, 2026

(54) TECHNOLOGIES FOR SERVICING AND OPERATING LIQUID COOLING SYSTEMS FOR HIGH-PERFORMANCE COMPUTING SYSTEMS

(71) Applicant: ECOLAB USA Inc., St. Paul, MN (US)

(72) Inventors: Robert M. LOWE, Chicago, IL (US); Robert S. WALICKI, Oak Park, IL (US); Matthew McMULLEN, Seattle, WA (US); Chris BIGGERS, Acworth, GA (US)

(73) Assignee: ECOLAB USA Inc., St. Paul, MN (US)

(21) Appl. No.: 19/210,723

(22) Filed: May 16, 2025

Related U.S. Application Data
(60) Provisional application No. 63/721,981, filed on Nov. 18, 2024.
(60) Provisional application No. 63/721,987, filed on Nov. 18, 2024.

(51) Int. Cl. H05K 7/20; G06F 1/20

(52) U.S. Cl. CPC H05K 7/20281; G06F 1/20; H05K 7/20272; H05K 7/20772; G06F 2200/201

(57) ABSTRACT

A system includes a liquid monitoring system adapted to be coupled to a secondary coolant loop that connects a high-performance computing system and a cooling distribution unit. The liquid monitoring system includes one or more liquid sensors fluidly coupled to the secondary coolant loop. The system includes a controller coupled to the liquid sensors. The system may include features that improve servicing or operations. The system may include modularity features for the cooling distribution unit. The system may include additional servicing equipment. The system may provide maintenance system improvements.

### TECHNICAL FIELD

The present disclosure generally relates to cooling technologies for computer systems. More particularly, this disclosure relates to liquid cooling systems for high-performance computing systems.

### BACKGROUND

Large computer systems, such as supercomputers, high-performance computing (HPC) systems, data centers, enterprise systems, and other large computer systems generate significant amounts of waste heat that must be managed. Traditionally, computer systems were air-cooled; however, many modern supercomputers and other large computer systems use liquid cooling systems. Liquid cooling may increase cooling efficiency and effectiveness as compared to air cooling, especially for extremely power-dense computing systems. Typical liquid cooling systems for large computing systems include a closed loop that is pressurized with coolant, such as water or a water/propylene glycol mixture.

In use, the coolant included in such a closed loop cooling system for computer systems may become degraded, contaminated, or otherwise change over time. Typical liquid cooling systems for computing systems may be manually inspected and serviced.

### BRIEF SUMMARY

Certain aspects of the present disclosure provide a system for computing device cooling liquid monitoring and service. The system comprises a liquid monitoring system adapted to be coupled to a secondary coolant loop, wherein the secondary coolant loop connects a high-performance computing system and a heat exchanger. The liquid monitoring system comprises a liquid cooling conduit in fluid communication with the secondary coolant loop and one or more sensors fluidly coupled to the liquid coolant conduit and/or the secondary coolant loop. The system also comprises a controller operatively coupled to the sensors of the liquid monitoring system and a service device removably coupled to the high-performance computing system, the heat exchanger, or the secondary coolant loop.

The service device may comprise a portable service device having a mobility feature. The service device may comprise a sensor, a filtration device, an ion exchange device, an ultraviolet light emitter, or any combination thereof. The service device may be coupled to a port on the heat exchanger, the high performance computing system including the data center racks, blades, and/or the liquid monitoring system.

The system may further comprise a filtering system coupled to the secondary coolant loop.

The one or more sensors have a hot-swappable capability. The heat exchanger may be a hot-swappable heat exchanger.

The liquid monitoring system is fully or partially drainable.

The liquid monitoring system may comprise a sanitary sample port.

The liquid monitoring system may comprise a device to remove entrained air from the secondary coolant loop.

The system may further comprise a buffering tank for emergency cooling.

In some embodiments, a cooling distribution unit comprises the heat exchanger. The cooling distribution unit may comprise a modularity feature.

The system may further comprise a fluid transfer cart for addition of fluids to the secondary coolant loop, a water preparation cart for pretreatment of the cooling liquid, and/or a glycol cart that performs final filtration of a cooling liquid additive/chemical from a bulk container. In some embodiments, a single cart comprises the fluid transfer cart, the water preparation cart, and the glycol cart.

The system may be configured to perform full-service commissioning verification. The system may be configured to provide a service application.

The controller may be configured to perform a maintenance operation automatically and/or in response to an operator command. The controller may be configured to reverse a flow direction of the cooling liquid. The controller may be configured to perform automated or semiautomated sample collection.

The present disclosure also provides a device for industrial water system servicing. The device comprises a structural frame coupled to a mobility feature; an inlet and an outlet coupled to a fluid conduit, wherein the inlet and the outlet are configured to removably couple to a component of an industrial water system; a chemical storage unit fluidly coupled to the fluid conduit, wherein the chemical storage unit is configured to supply an additive to the fluid conduit when the inlet or the outlet is coupled to the component of the industrial water system; and a maintenance device coupled to the structural frame and fluidly coupled to the fluid conduit, wherein the maintenance device is configured to perform an operation on a liquid from the fluid conduit when the inlet or the outlet is coupled to the component of the industrial water system.

The industrial water system may comprise a secondary coolant loop for a direct-to-chip cooling system. The component of the industrial water system may comprise a compute blade, a blade enclosure, or a cooling distribution unit (CDU). The chemical storage unit may be coupled to the structural frame.

The additive may be selected from the group consisting of a corrosion inhibitor, a scale inhibitor, a buffer, a dispersant, a biocide, a scouring agent, a viscosity modifier, a heat transfer additive, a surfactant, a glycol, a fluorescent compound, a biostatic additive, copper, silver, a cleaning agent, water, and any combination thereof.

The maintenance device may comprise a filter, an ion exchange device, an ultraviolet light emitter, an ultrasound device, or any combination thereof.

The device may further comprise a measurement device coupled to the structural frame and fluidly coupled to the fluid conduit, wherein the measurement device is configured to generate data indicative of a property of the liquid within the fluid conduit; and a controller coupled to the structural frame and operatively coupled to the measurement device, wherein the controller is configured to receive the data from the measurement device.

The measurement device may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, a microbiology sensor, an oxidation-reduction potential sensor, a device for measuring organic and/or inorganic fouling, a refractometer, or any combination thereof.

The present disclosure also provides a method for servicing a direct computing cooling system. The method comprises fluidly connecting a service device to an asset of the direct computing cooling system; circulating, by the service device, a cleaning fluid within the asset until a first measured parameter of liquid coolant of the asset reaches a first predetermined threshold; and in response to the first measured parameter reaching the first predetermined threshold, filling, by the service device, the asset with additional liquid coolant until a second measured parameter of the liquid coolant reaches a second predetermined threshold.

The method may further comprise attaching the asset to a secondary coolant loop of the direct computing cooling system in response to the second measured parameter reaching the second predetermined threshold. The asset may comprise a compute blade, a blade enclosure, a cooling distribution unit, or the secondary cooling loop.

The cleaning fluid may comprise liquid coolant, water, biocide, or inhibitor. The first measured parameter may comprise turbidity, and the second measured parameter may comprise turbidity, glycol wt. %, pH, conductivity, temperature, flow rate, fluorescence, color, dissolved oxygen, pressure, differential pressure, vibration, IR light, alkalinity, entrained air, particle size, microbiology, oxidation-reduction potential, organic and/or inorganic fouling, or index of refraction.

The method may further comprise measuring, by the service device, the first measured parameter and the second measured parameter of the liquid coolant with a measurement device of the service device. The measurement device may comprise a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, a microbiology sensor, an oxidation-reduction potential sensor, a device for measuring organic and/or inorganic fouling, a refractometer, or any combination thereof.

The method may further comprise coupling a reject line of the service device to a storage container, wherein returned liquid coolant from the asset is stored in the storage container while filling the asset; and closing, by the service device, the reject line in response to the second measured parameter reaching the second predetermined threshold.

Circulating the cleaning fluid within the asset may further include filtering the liquid coolant by a filter device of the service device. Circulating the cleaning fluid within the asset may further include adding, by the service device, a cleaning solution, water, glycol, or a water solution with cleaning or treatment chemistry to the liquid coolant. The method may further comprise generating, by the service device, a certificate of verification in response to the second measured parameter reaching the second predetermined threshold. The method may further comprise generating, by the service device, a physical representation of the certificate of verification. The method may further comprise attaching the physical representation of the certificate of verification to the asset.

The present disclosure also provides a method for management of an industrial water system. The method comprises linking, by a controller, a first component of an industrial water system to a maintenance operation performed with the maintenance operation; verifying, by the controller, performance of the maintenance operation; and generating, by the controller, a certificate of verification in response to verifying the performance of the maintenance operation, wherein the certificate of verification is indicative of the first component and the maintenance operation. The first component may comprise a compute blade, a blade enclosure, a cooling distribution unit, or a secondary cooling loop of the industrial water system.

The method may further comprise attaching a mobile servicing device to the industrial water system; and performing the maintenance operation with the mobile servicing device after attaching the mobile servicing device to the industrial water system.

The method may further comprise causing, by the controller, the performance of the maintenance operation. Causing the performance of the maintenance operation may comprise adding an additive to the industrial water system.

The additive may comprise a corrosion inhibitor, a scale inhibitor, a buffer, a dispersant, a biocide, a scouring agent, a viscosity modifier, a heat transfer additive, a surfactant, a glycol, a fluorescent compound, a biostatic additive, copper, silver, a cleaning agent, water, and any combination thereof.

Causing the performance of the maintenance operation may comprise activating a maintenance device coupled to the industrial water system. The maintenance device may comprise a filter, an ion exchange device, an ultraviolet light emitter, an ultrasound device, or any combination thereof.

Linking the first component may comprise receiving a bar code scan indicative of the first component from a mobile computing device.

Verifying the performance of the maintenance operation may comprise measuring a property of a liquid in the industrial water system and comparing, by the controller, the property to a predetermined threshold.

Generating the certificate of verification may comprise generating a digital certificate and/or generating a physical certificate and attaching the physical certificate to the first component.

The foregoing has outlined rather broadly the features and technical advantages of the present disclosure in order that the detailed description that follows may be better understood. Additional features and advantages of the disclosure will be described hereinafter that form the subject of the claims of this application. It should be appreciated by those skilled in the art that the conception and the specific embodiments disclosed may be readily utilized as a basis for modifying or designing other embodiments for carrying out the same purposes of the present disclosure. It should also be realized by those skilled in the art that such equivalent embodiments do not depart from the spirit and scope of the disclosure as set forth in the appended claims.

### BRIEF DESCRIPTION OF THE SEVERAL VIEWS OF THE DRAWINGS

A detailed description of the invention is hereafter described with specific reference being made to the drawings in which:

FIG. 1 shows a simplified block diagram of a system for high-performance computing with liquid cooling;

FIG. 2 shows a simplified block diagram of at least one embodiment of a liquid monitoring system for a high-performance computing system with liquid cooling;

FIG. 3 shows a simplified block diagram of at least one embodiment of another liquid monitoring system for a high-performance computing system with liquid cooling;

FIG. 4 shows a diagram of at least one embodiment of a coolant blade of the liquid monitoring system of FIG. 3;

FIG. 5 shows a simplified block diagram of at least one additional embodiment of a liquid monitoring system for a high-performance computing system with liquid cooling;

FIG. 6 shows a simplified block diagram of another embodiment of a liquid monitoring system for a high-performance computing system with liquid cooling;

FIG. 7 shows a simplified block diagram of at least one embodiment of a mobile servicing device that may be used with a system or component of FIGS. 1-6;

FIG. 8 is a perspective view of at least one embodiment of a mobile servicing device of FIG. 7; and

FIG. 9 is a simplified flow diagram of at least one embodiment of a method for maintenance or commissioning for a system or component as shown in FIGS. 1-8.

### DETAILED DESCRIPTION

Various embodiments are described below with reference to the drawings in which like elements generally are referred to by like numerals. The relationship and functioning of the various elements of the embodiments may better be understood by reference to the following detailed description. However, embodiments are not limited to those illustrated in the drawings. It should be understood that the drawings are not necessarily to scale, and in certain instances details may have been omitted that are not necessary for an understanding of embodiments disclosed herein, such as conventional fabrication and assembly.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

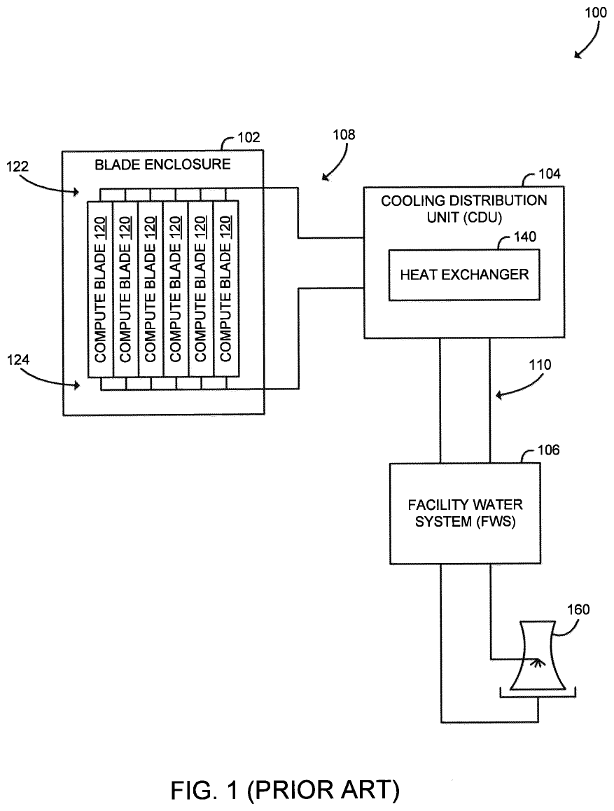

Referring now to FIG. 1, a typical computing system 100 with liquid cooling includes a computing blade enclosure 102 that includes multiple compute blades 120. Although illustrated as including a blade enclosure 102, it should be understood that the system 100 may include any appropriate chassis, rack, frame, or other enclosure configured to support multiple compute blades 120 or other high-density computing devices. Additionally, although illustrated as including a single blade enclosure 102, it should be understood that the system 100 may include multiple blade enclosures 102 which may be arranged in rows or otherwise combined to form a high-performance computing (HPC) system, supercomputer, computing cluster, data center, server farm, or other computing system that includes liquid-cooled computing units.

Each of the compute blades 120 may be embodied as individual computing devices, servers, nodes, or other heat-generating computing devices. The blade enclosure 102 includes a number of bays or slots of standardized dimensions, and each compute blade 120 may have a standard size and/or other standardized physical characteristics such that each compute blade 120 may be received in a corresponding bay or slot of the blade enclosure 102. In some embodiments, the bays or slots may have a height or other dimension that is smaller than a typical “1U” rack height, allowing the blade enclosure 102 to support high compute density.

The blade enclosure 102 further includes a supply manifold 122 and a return manifold 124, which are configured to distribute coolant (e.g., cooling liquid, such as water or a water/propylene glycol mixture) to the compute blades 120 and to collect the coolant from the compute blades 120. The blade enclosure 102 may further include power, networking, and/or other connections or components configured to support operations of the compute blades 120.

As shown, the blade enclosure 102 is coupled to one or more cooling distribution units (CDU) 104 via a technology cooling system (TCS) 108, also called a secondary coolant loop 108. Although shown as a CDU 104, this component of the system may comprise a heat exchanger in any embodiment disclosed herein. In some embodiments, such as shown in FIGS. 1-3, a CDU may comprise the heat exchanger. TCS 108 may be embodied as one or more pipes or other liquid conduits capable of transferring coolant from the CDU 104 to the blade enclosure 102 and back. The CDU 104 includes a heat exchanger 140 configured to extract heat from the TCS 108. The CDU 104 may also include one or more additional components configured to support circulating coolant to the blade enclosure 102, such as pumps, thermostats, filters, and/or other components.

The CDU 104 is coupled to a facility water system (FWS) 106 via a primary loop 110. The primary loop 110 may be embodied as one or more pipes or other liquid conduits capable of transferring facility water or other coolant between the FWS 106 and the CDU 104. The FWS 106 is illustratively coupled to a cooling tower 160, which rejects heat from the FWS 106 to the environment. Additionally, the FWS 106 may include and/or be coupled to one or more additional components to support rejecting heat, such as one or more chillers, additional liquid loops, thermostats, condensers, and/or other components.

In use, the CDU 104 supplies cool coolant to the blade enclosure 102 via the TCS 108. The coolant may be maintained at an appropriate temperature, such as a temperature above a dew point at the location of the blade enclosure 102 (e.g., about 30° F., about 35° F., about 40° F., about 45° F., etc.) in order to avoid condensation or other issues. The coolant is distributed through the supply manifold 122 to the compute blades 120. In each of the compute blades 120, the coolant flows through one or more cold plates, water blocks, or other cooling components coupled to processors, graphical processing units (GPUs), application specific integrated circuits (ASICs), or other heat-generating components of the compute blades 120. Warm coolant from the compute blades 120 is collected by the return manifold 124 and returned to the CDU 104. Heat from the warm coolant is transferred to the FWS 106 using the heat exchanger 140, and then this heat is rejected to the environment using the cooling tower 160.

Although illustrated as including a single blade enclosure 102 and CDU 104, it should be understood that in some embodiments, the system 100 may include multiple blade enclosures 102 and CDUs 104. Additionally, in some embodiments, the CDU 104 may use a different technique to cool the coolant in the TCS 108. For example, in some embodiments, the CDU 104 may be air-cooled and may not require a connection to the facility primary loop 110.

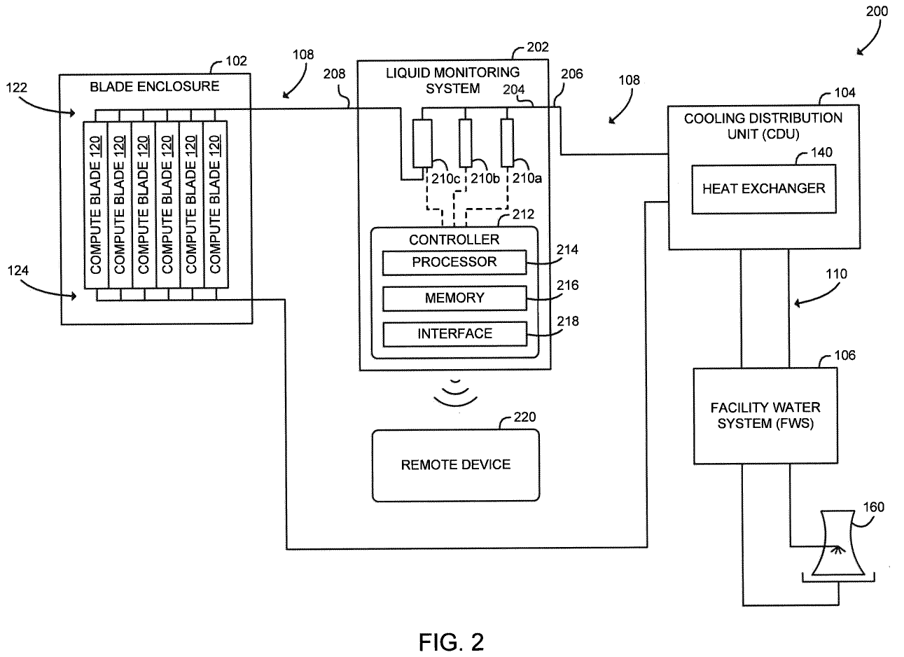

Referring now to FIG. 2, a system 200 for liquid coolant monitoring for a liquid cooled computing system includes a blade enclosure 102, CDU 104, and FWS 106 similar to those described above in connection with FIG. 1. Additionally, and as shown in FIG. 2, the system 200 includes a liquid monitoring system 202 that is coupled to the secondary loop 108 between the CDU 104 and the blade enclosure 102, although a monitoring system 202 may be located at any point in FIG. 2, such as downstream of the blade enclosure 102, upstream and/or downstream of the FWS 106, and/or upstream and/or downstream of the CDU 104. The liquid monitoring system 202 includes an internal liquid conduit 204 that extends between an inlet 206 and an outlet 208. As shown, the inlet 206 is coupled to the CDU 104 via the TCS 108, and the outlet 208 is coupled to the inlet manifold 122 of the blade enclosure 102 via the TCS 108. Thus, coolant provided by the CDU 104 passes through the conduit 204 of the liquid monitoring system 202 before being provided to the blade enclosure 102. It should be understood that in other embodiments, the liquid monitoring system 202 may be coupled to the system 200 in one or more other configurations. For example, in an embodiment, the liquid monitoring system 202 may be coupled to the return leg of the TCS 108 (i.e., coupled between the return manifold 124 of the blade enclosure 102 and the CDU 104. As another example, in an embodiment with multiple blade enclosures 102, the liquid monitoring system 202 may be coupled between any of the blade enclosures 102.

The liquid monitoring system 202 further includes one or more sensors 210 that are each coupled to the conduit 204. Illustratively, the liquid monitoring system 202 includes three sensors 210a, 210b, 210c, however, in other embodiments, the system 202 may include a different number of sensors 210, such as one, two, four, five, six, seven, eight, nine, ten, or more. Each of the sensors 210 may be embodied as any electronic sensor capable of monitoring or otherwise measuring one or more properties/parameters of the coolant, such as turbidity, pH, percentage propylene glycol, conductivity, fluorescence, color, dissolved oxygen content, flow rate, pressure, or other parameters. Those measured parameters may be indicative of coolant health. For example, the sensors 210 may include a sensor for online-refractometry to measure weight percentage propylene glycol in the coolant. As another example, the sensors 210 may include a filter fitted with pressure sensors for measuring differential pressure across the filter as an additional data point for fluid health and particulate. As another example, the sensors 210 may measure absorbance or fluorescence to monitor pH via an indicator. As another example, the sensors 210 may measure color to determine coolant health, for example by monitoring the inherent color of the propylene glycol, color of a dye added as an inert additive, or measuring UV absorbance as a surrogate for total organic carbon (TOC). As another example, the sensors 210 may measure dissolved oxygen in the coolant, which may be indicative of glycol degradation. As another example, the sensors 210 may measure pressure and vibration, such as at a recirculation pump outlet. In some embodiments, the liquid monitoring system 202 may include additional sensors that may not be directly fluidly coupled to the conduit 204, such as leak sensors, fluid reservoir volume sensors, or other sensors.

In some embodiments, the liquid monitoring system 202 may be used to monitor treated water systems in addition to or alternatively to liquid cooling systems. In those embodiments, the liquid monitoring system 202 may include the sensors 210 described above (without the refractometer in some embodiments) along with additional sensors for microbiology sensing, oxidation-reduction potential (ORP), or other sensors for monitoring for inhibitor residuals. In some embodiments, the liquid monitoring system 202 may include sensors 210 for measuring organic and inorganic deposits or other fouling.

Each of the sensors 210 is communicatively coupled to a controller 212. The illustrative controller 212 may be embodied as any programmable logic controller, microcontroller, microprocessor, or other device capable of performing the functions described herein. To do so, the controller 212 may include a number of electronic components commonly associated with units utilized in the control of electronic and electromechanical systems. For example, the controller 212 may include, amongst other components customarily included in such devices, a processor 214 and a memory device 216. The processor 214 may be any type of device capable of executing software or firmware, such as a microcontroller, microprocessor, digital signal processor, or the like. The memory 216 may be embodied as one or more volatile and/or non-volatile memory device. The memory device 216 is provided to store, amongst other things, instructions in the form of, for example, a software routine (or routines) which, when executed by the processor 214, allows the controller 212 to monitor sensor data from the sensors 210 as described herein. The controller 212 also includes an interface circuit 218, which may be embodied as any analog and/or digital electrical circuit(s), component, or collection of components capable of performing the functions described herein. The interface circuit 218 converts output signals (e.g., from the sensors 210) into signals which are suitable for presentation to an input of the processor 212. In particular, in some embodiments the interface circuit 218, by an analog-to-digital (A/D) converter, or the like, converts analog signals into digital signals for use by the processor 214. Similarly, the interface circuit 218 may convert signals from the processor 214 into output signals which are suitable for presentation to the electrically-controlled components associated with system 202 (e.g., one or more pumps or other components). In particular, the interface circuit 218, by use of a variable-frequency signal generator, digital-to-analog (D/A) converter, or the like, may convert digital signals generated by the processor 214 into analog signals for use by the electronically-controlled components associated with the system 202. It is contemplated that, in some embodiments, the interface circuit 218 (or portions thereof) may be integrated into the processor 214.

The controller 212 may be in wireless communication with a remote computing device 220. The remote computing device 220 may be embodied as any controller, computer, server device, or other device capable of performing the functions described herein. In some embodiments, the remote device 220 may be embodied as a gateway device or other device configured to receive data from the controller 212 and forward that data to another remote device 220 such as a digital platform server. For example, in some embodiments the remote device 220 may be embodied as a Nalco Global Gateway. Accordingly, in some embodiments the remote computing device 220 may include components typically found in a server computer, such as a process, a memory, and various interface circuits. The above description of similar components of the controller 212 is applicable to similar components of the remote device 220 and for clarity is not repeated herein.

The illustrative liquid monitoring system 202 may be physically installed on a stand, a sled, a skid, a plate, or other physical structure to support components of the liquid monitoring system 202 and to allow for physical installation of the liquid monitoring system 202 at the computing system 100. For example, in some embodiments, the liquid monitoring system 202 may be mounted to a freestanding stand that may be positioned near the CDU 104 and the blade enclosure 102. In some embodiments, the CDU (and/or a heat exchanger) may comprise the liquid monitoring system, or any component thereof. The secondary loop 108 may be thus routed from the heat exchanger and/or CDU 104 to the blade enclosure 102 through the liquid monitoring system 202.

As another example, in some embodiments the liquid monitoring system 202 may be mounted to a sled, a skid, a plate, or other structure that may be physically attached to the blade enclosure 102, the CDU 104, or another structure, such as a heat exchanger. For example, in some embodiments, the liquid monitoring system 202 may be attached to a wall or other structure near the blade enclosure 102 and the CDU 104. As another example, in some embodiments the liquid monitoring system 202 may be attached to a side panel of the blade enclosure 102. This arrangement may allow for access to the compute blades 120 while also providing access to the liquid monitoring system 202, for maintenance or other tasks. As yet another example, the liquid monitoring system 202 may be attached to a front panel of a heat exchanger and/or the CDU 104, which allows for access to the liquid monitoring system 202 for maintenance or other tasks.

Thus, system 200, including the liquid system monitoring system 202, allows for automated, real time or near real time monitoring of coolant properties for liquid cooled computing system. Compared to previous liquid cooled computing systems, the system 200 may allow for monitoring additional coolant properties continually, with improved accuracy or otherwise improved monitoring quality. Such monitoring may allow for improved coolant quality (e.g., ensuring parameters remain within accepted ranges or thresholds), which in turn may improve cooling performance and/or computing performance of the system 200.

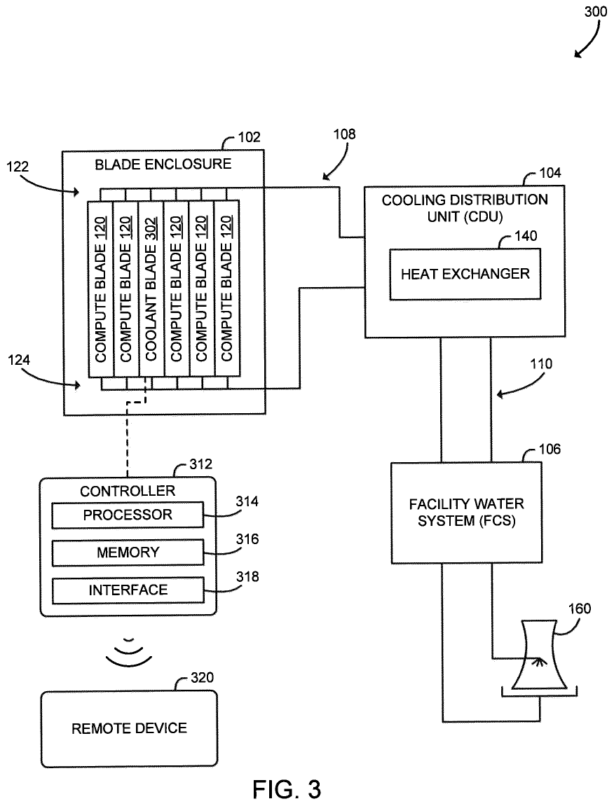

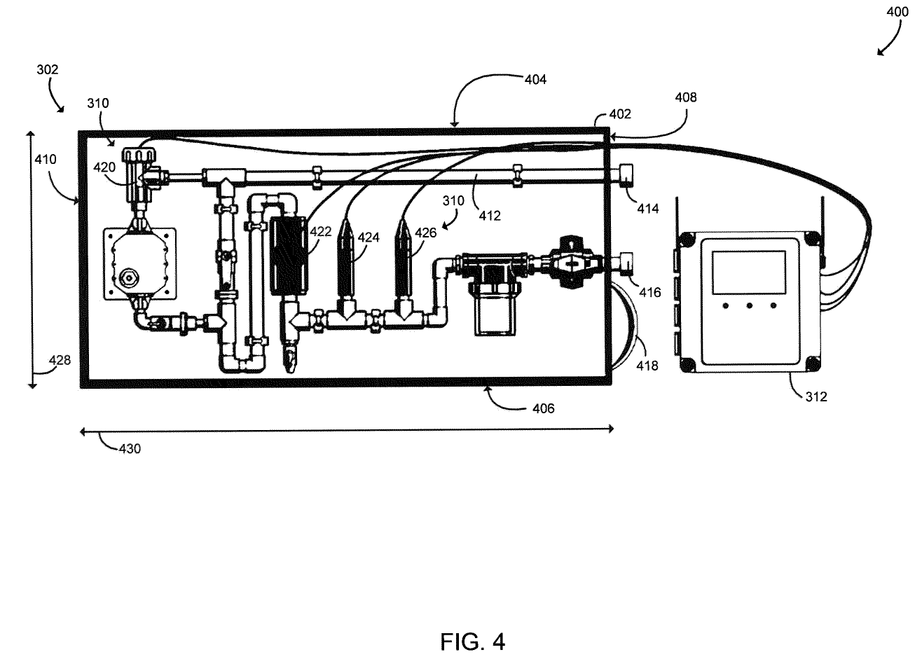

Referring now to FIG. 3, a system 300 for liquid cooling monitoring for a liquid cooled computing system includes a blade enclosure 102, CDU 104, and FWS 106 similar to those described above in connection with FIGS. 1 and 2. Additionally, and as shown in FIG. 3, the system 300 includes a coolant blade 302 mounted to the blade enclosure 102. As described further below, the coolant blade 302 includes sensors 310 (illustratively shown in FIG. 4) and a cooling liquid conduit similar to the liquid monitoring system 202 shown in FIG. 2. Additionally, the coolant blade 302 is adapted to be received in the same bays or slots of the blade enclosure 102 as the compute blades 120. In particular, the coolant blade is coupled to the supply manifold 122 and the return manifold 124. As coolant circulates through the secondary loop 108, a portion of the coolant passes through the coolant blade 302, which uses sensors to monitor one or more parameters of the coolant, similar to the liquid monitoring system 202 of FIG. 2. The secondary loop 108 has a relatively small volume of coolant, and thus over time, all or substantially all of the coolant within the secondary loop 108 passes through the coolant blade 302 for monitoring.

As shown in FIG. 3, the coolant blade 302 is communicatively coupled to a controller 312, which includes a processor 314, a memory 316, and an interface 318. The illustrative controller 312 may be the same as or similar to the controller 212 of FIG. 2. As shown, the controller 312 may also be in communication with a remote computing device 320, which may be the same as or similar to the remote computing device 220 of FIG. 2. Accordingly, the description of the controller 212 and its components is also applicable to the controller 312 and its components, and the description of the remote computing device 220 is also applicable to the remote computing device 320. To improve clarity of this disclosure, those descriptions are not repeated herein.

Thus, the system 300, including the coolant blade 302, allows for automated, real time or near real time monitoring of coolant parameters for liquid cooled computing system. Compared to previous liquid cooled computing systems, and similar to the system 200, the system 300 may allow for monitoring additional coolant parameters continually, with improved accuracy or otherwise improved monitoring quality. Such monitoring may allow for improved troubleshooting and other maintenance of the coolant system, thus improving coolant quality (e.g., by performing early maintenance to ensure parameters/properties remain within accepted ranges or thresholds). Improved maintenance, troubleshooting, and/or coolant quality may thus improve cooling performance and/or computing performance of the system 300. Additionally, by using a coolant blade 302 that is interchangeable with a compute blade 120, the system 300 may provide improved coolant monitoring without requiring modifications to existing liquid cooling systems (e.g., without requiring connection to the secondary loop 108 outside of the blade enclosure 302). Thus, the system 300 may reduce costs or otherwise improve efficiency associated with liquid coolant monitoring. Further, the coolant blade 302 may be incorporated into the system 300 without requiring additional space for liquid coolant monitoring, which is desirable for many high-performance computing systems in which space is at a premium.

Referring now to FIG. 4, diagram 400 illustrates one potential embodiment of a coolant blade 302 of the system 300. The illustrative coolant blade 302 includes a chassis 402 that supports and encloses components of the coolant blade 302. The chassis 402 illustratively includes a pair of opposing side panels 404, 406, a front panel 408, and a rear panel 410. The chassis 402 may also include a top panel and a bottom panel, which are not specifically shown in FIG. 4.

The illustrative coolant blade 302 includes a liquid conduit 412 or other passage that extends throughout the interior of the chassis 402. The liquid conduit 412 may include one or more pipes, valves, and other components capable of containing pressurized coolant. The coolant blade 302 further includes an inlet connector 414 and an outlet connector 416 that are fluidly coupled to the liquid conduit 412. The connectors 414, 416 are configured to connect to the secondary loop 108 of the system 300, for example by connecting to the supply manifold 122 and the return manifold 124 or other liquid coolant handling components of the blade enclosure 102. The connectors 414, 416 are illustratively quick connect connectors; however, the connectors 414, 416 may be embodied as any liquid connector compatible with the blade enclosure 102.

The chassis 404 further includes a handle 418 extending outward from the front panel 408. The handle 418 may be used to facilitate inserting the chassis 402 into a bay or slot of the blade enclosure 102. Illustratively, the connectors 414, 416 also extend outwardly from the front panel 408 of the chassis 402, so that the connectors 414, 416 are accessible when the chassis 402 is inserted in the blade enclosure 102. In other embodiments, the connectors 414, 416 may extend from the rear panel 410 or be otherwise arranged relative to the chassis 402 to connect to the blade enclosure 102 when the chassis 402 is inserted in the blade enclosure 102. Similarly, the chassis 402 may include one or more locking levers, attachment devices, or other mechanical features to support installation in the blade enclosure 102.

As shown, the illustrative coolant blade 302 includes multiple sensors 310 that are fluidly coupled to the liquid conduit 412 and positioned in an interior of the chassis 402. Illustratively, the diagram 400 includes four sensors 420, 422, 424, 426 fluidly coupled to the liquid conduit 412. Similar to the sensors 210 of the liquid monitoring system 202 of FIG. 2, each of the sensors 310 may be embodied as any electronic sensor capable of monitoring or otherwise measuring one or more parameters of the coolant, such as turbidity, pH, percentage propylene glycol, conductivity, temperature, flow rate, or other parameters. Those measured parameters may be indicative of coolant health. For example, the sensors 310 may include sensor for online-refractometry to measure percentage propylene glycol. As another example, the sensors may include a filter fitted with pressure sensors for measuring differential pressure across the filter as an additional data point for fluid health and particulate. As another example, the sensors may measure absorbance or fluorescence to monitor pH via an indicator. As described above, in some embodiments, the sensors may include additional sensors for microbiology sensing, oxidation-reduction potential (ORP), or other sensors for monitoring for inhibitor residuals.

The sensors 420, 422, 424, 426 are illustratively communicatively coupled to the controller 312. As described further below, and similar to the controller 212, the controller 312 is configured to receive sensor data from the sensors, process the sensor data, and in some embodiments to transmit the sensor data to one or more remote devices 320. As shown, in the illustrative embodiment, the controller 312 is a component separate from the chassis 402 and connected to the sensors 420, 422, 424, 426. In this illustrative embodiment, the controller 312 may be attached or otherwise positioned in an accessible location. For example, the controller 312 may be attached to an outside surface of the blade enclosure 102 or another location that is accessible by a maintenance technician or other user. Additionally, although illustrated as using wired connections to the sensors 310, it should be understood that in some embodiments the controller 312 may be connected to the sensors 310 wirelessly.

In some embodiments, some or all components of the controller 312 may be included inside or otherwise incorporated with the chassis 402 of the coolant blade 302. For example, in an embodiment the controller 312 may be positioned inside the chassis 402 and connected to the sensors 420, 422, 424, 426 by wires. In some embodiments, one or more screens, buttons, or other user interface devices of the controller 312 may be user-accessible, for example by being positioned on (or otherwise accessible through) the front panel 408 of the chassis 402.

As shown, the chassis 402 includes a width 428 and a depth 430. The chassis 402 may also include a height (not shown). Those dimensions may be similar to standardized dimensions of one or more compute blades 120 that are compatible with the blade enclosure 102. For example, in some embodiments, the chassis 402 may have width 428, depth 430, and height equal to a full-height blade or a double-height blade used with a blade enclosure 102. As another example, in some embodiments the chassis 402 may have a width 428 equal to a standard rack width (e.g., 19 inches or another dimension).

In some embodiments, the chassis 402 may include additional features providing access to the secondary loop 108 for maintenance or other purposes. For example, in an embodiment, the chassis 402 may include an additional port positioned on the front panel 408 or other accessible location of the chassis 402 that is fluidly coupled to the liquid conduit 412, and thus to the secondary loop 108. Continuing that example, pressurized cartridges, bottles, or other containers of chemicals, such as propylene glycol, may be attached to the liquid conduit 412 using this port in order to add those chemicals to the secondary loop 108. Such additions may be based on measurements of the coolant generated by the coolant blade 302. Accordingly, the coolant blade 302 may allow for addition of chemicals to the secondary loop 108 without interrupting coolant flow from the CDU 104 and with reduced risk of contamination compared to typical systems.

In some embodiments, the chassis 402 may include additional sensors or other data sources for the controller 312. For example, in an embodiment the chassis may include one or more leak detection sensors. Those sensors may not be fluidly coupled to the liquid conduit 412.

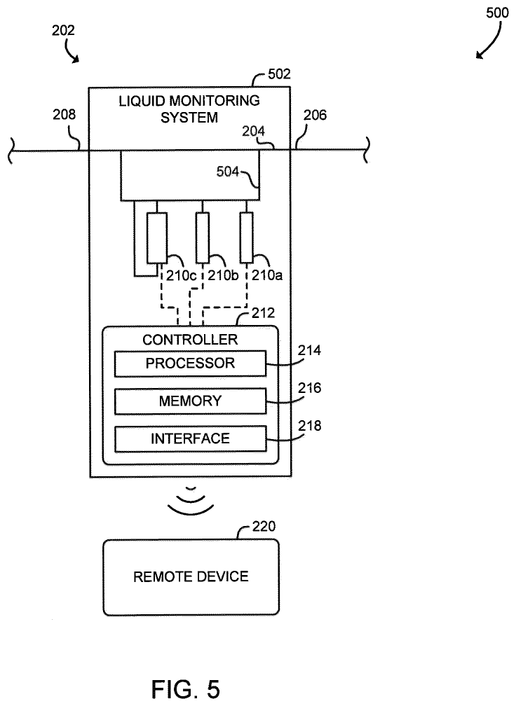

Referring now to FIG. 5, diagram 500 illustrates another potential embodiment of a liquid monitoring system 502 that may be used with the system 200 of FIG. 2. As shown, the illustrative system 502 includes many of the same components of the liquid monitoring system 202 shown in FIG. 2, the description of which is applicable to the corresponding components of the liquid monitoring system 502 and is not repeated herein so as not to obscure the present disclosure. Thus, the liquid monitoring system 502 may be used with the system 200 in place of and/or together with the liquid monitoring system 202, for example by coupling the inlet 206 to the CDU 104 via the TCS 108, and coupling the outlet 208 to the inlet manifold 122 of the blade enclosure 102 via the TCS 108.

As shown, the liquid monitoring system 502 includes an internal liquid conduit 204 that extends between the inlet 206 and the outlet 208. The liquid monitoring system 502 further includes a side channel 504 coupled to the liquid conduit 204. The sensors 210 are coupled to the side channel 504. Accordingly, at least a part of the coolant received at the inlet 206 passes through the conduit 204 and then the side channel 504, wherein the coolant may be measured by one or more of the sensors 210. The TCS 108 has a relatively small volume of coolant, and thus over time, all or substantially all of the coolant within the TCS 108 passes through the side channel 504 for monitoring.

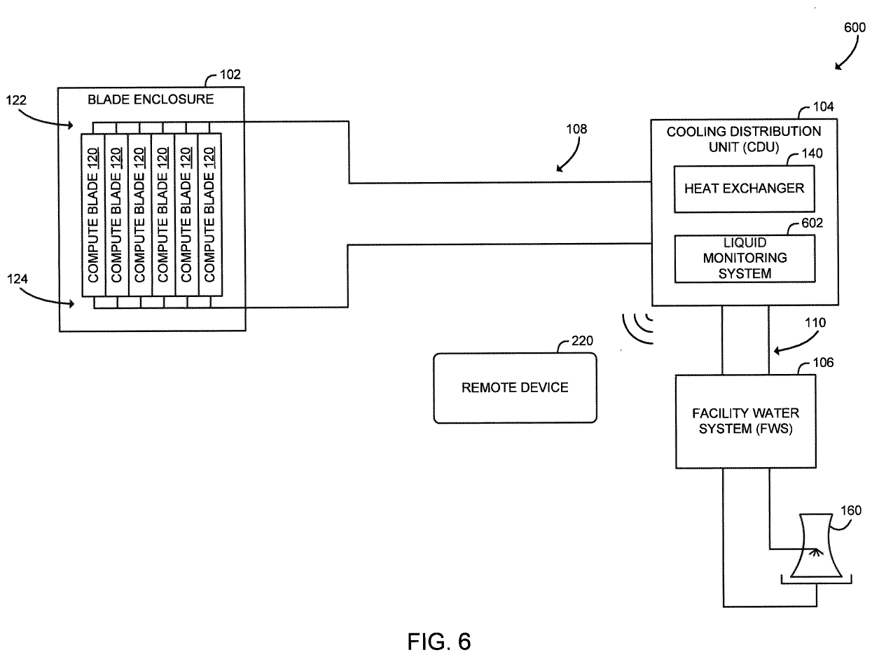

Referring now to FIG. 6, a system 600 for liquid coolant monitoring for a liquid cooled computing system includes a blade enclosure 102, CDU 104, and FWS 106 similar to those described above in connection with FIGS. 1 and 2. Additionally, and as shown in FIG. 6, the system 600 includes a liquid monitoring system 602 that is incorporated in the CDU 104. The illustrative system 602 may include the same components as the liquid monitoring system 202 shown in FIG. 2 and/or the liquid monitoring system 502 shown in FIG. 5, the description of which is applicable to the corresponding components of the liquid monitoring system 602 and is not repeated herein so as not to obscure the present disclosure.

As shown, the illustrative liquid monitoring system 602 is incorporated in the CDU 104. For example, the system 602 may be included within the same cabinet or other enclosure as the CDU 104. In some embodiments, the system 602 may be a modular component of the CDU 104 and/or may be removably attached to the CDU 104. In some embodiments the system 602 may be physically attached to an internal or external surface of the CDU 104 or otherwise co-located with the CDU 104.

As used herein, the term “controller” refers to a manual operator or an electronic device having components, such as a processor, memory device, digital storage medium, a communication interface including communication circuitry operable to support communications across any number of communication protocols and/or networks, a user interface (e.g., a graphical user interface that may include cathode ray tube, liquid crystal display, plasma display, touch screen, or other monitor), and/or other components.

The controller is preferably operable for integration with one or more application-specific integrated circuits, programs, computer-executable instructions or algorithms, one or more hard-wired devices, wireless devices, and/or one or more mechanical devices. Moreover, the controller is operable to integrate the feedback, feed-forward, and/or predictive loop(s) of the invention. Some or all of the controller system functions may be at a central location, such as a network server, for communication over a local area network, wide area network, wireless network, internet connection, microwave link, infrared link, wired network (e.g., Ethernet) and the like. In addition, other components, such as a signal conditioner or system monitor, may be included to facilitate signal transmission and signal-processing algorithms.

In certain aspects, the controller includes hierarchy logic to prioritize any measured or predicted properties associated with system parameters. For example, the controller may be programmed to prioritize percentage propylene glycol over conductivity, or vice versa. It should be appreciated that the object of such hierarchy logic is to allow improved control over the system parameters and to avoid circular control loops.

As described above, the system 200, 300, 600 may comprise a plurality of sensors, which are capable of analyzing the coolant and transmitting data regarding the coolant to the controller. In certain embodiments the system is implemented to have the plurality of sensors provide continuous or intermittent feedback, feed-forward, and/or predictive information to the controller, which can relay this information to a relay device, such as the Nalco Global Gateway, which can transmit the information via cellular communications to a remote device, such as a cellular telephone, computer, computer server, and/or any other device that can receive cellular communications. This remote device (or an operator of the remote device) can interpret, store, or otherwise process the information and in some embodiments may automatically send a signal (e.g. electronic instructions) back, through the relay device, to the controller to cause the controller to perform certain operations.

Alternatively, an operator of the remote device that receives cellular communications from the controller can manually manipulate the system 202. The operator may communicate instructions, through the remote device, cellularly or otherwise, to the controller 212 and the controller 212 can make adjustments to the system 202. For example, the operator can receive a signal or alarm from the remote device through a cellular communication from the controller 212 and send instructions or a signal back to the controller 212. The controller and/or the remote device is also capable of making any of the foregoing adjustments or modifications automatically without the operator actually sending or inputting any instructions. Preset parameters or programs are entered into the controller or remote device so that the controller or remote device can determine if a measured property is outside of an acceptable range. Based on the information received by the plurality of sensors, the controller or remote device can make appropriate adjustments to the system 202 or send out an appropriate alert.

In certain embodiments, the remote device or controller can include appropriate software to receive data from the plurality of sensors and determine if the data indicates that one or more measured properties of the coolant are within, or outside, an acceptable range. The software can also allow the controller or remote device to determine appropriate actions that should be taken to remedy the property that is outside of the acceptable range. For example, if the measured percentage of propylene glycol is below the acceptable range, the software allows the controller or remote device to make this determination and take remedial action, such as alerting a pump to inject propylene glycol into the coolant.

Alternatively, an operator of the remote device that receives cellular communications from the controller can manually manipulate the system through the remote device. The operator may communicate instructions, through the remote device, cellularly or otherwise, to the controller and the controller can make adjustments to the rate of chemical addition of the chemical injection pumps. For example, the operator can receive a signal or alarm from the remote device through a cellular communication from the controller and send instructions or a signal back to the controller using the remote device to turn on one or more of the chemical injection pumps, turn off one or more of the chemical injection pumps, increase or decrease the amount of chemical being added to the coolant by one or more of the injection pumps, or any combination of the foregoing. The controller and/or the remote device is also capable of making any of the foregoing adjustments or modifications automatically without the operator actually sending or inputting any instructions. Based on the information received by the plurality of sensors, the controller or remote device can make appropriate adjustments to the pumps or send out an appropriate alert.

The sensors disclosed herein are operable to sense and/or predict a property associated with the coolant or system parameter and convert the property into an input signal, e.g., an electric signal, capable of being transmitted to the controller. A transmitter associated with each sensor transmits the input signal to the controller. The controller is operable to receive the transmitted input signal, convert the received input signal into an input numerical value, analyze the input numerical value to determine if the input numerical value is within an optimum range, generate an output numerical value, convert the output numerical value into an output signal, e.g., an electrical signal, and transmit the output signal to a receiver, such as a remote device, such as a computer or cellular telephone, incorporating receiver capabilities. The receiver receives the output signal and either alerts an operator, or the receiver can be operable to cause a change in the system 202, if the output numerical value is not within the acceptable range for that property.

Data transmission of measured parameters or signals to remote monitoring devices, such as computers or cellular telephones, or other system components is accomplished using any suitable device, and across any number of wired and/or wireless networks, including as examples, WiFi, WiMAX, Ethernet, cable, digital subscriber line, Bluetooth, cellular technologies (e.g., 2G, 3G, Universal Mobile Telecommunications System (UMTS), GSM, Long Term Evolution (LTE), or more) etc. The Nalco Global Gateway is an example of a suitable device. Any suitable interface standard(s), such as an Ethernet interface, wireless interface (e.g., IEEE 802.11a/b/g/x, 802.16, Bluetooth, optical, infrared, radiofrequency, etc.), universal serial bus, telephone network, the like, and combinations of such interfaces/connections may be used.

As used herein, the term “network” encompasses all of these data transmission methods. Any of the described devices (e.g., archiving systems, data analysis stations, data capturing devices, process devices, remote monitoring devices, chemical injection pumps, etc.) may be connected to one another using the above-described or other suitable interface or connection.

In some embodiments, system parameter information is received from the system and archived. In certain embodiments, system parameter information is processed according to a timetable or schedule. In some embodiments, system parameter information is immediately processed in real-time or substantially real-time. Such real-time reception may include, for example, “streaming data” over a computer network.

In some embodiments, the system 200, 300, 600 may include additional equipment that provides service and operational improvements. In some embodiments, the system 200, 300, 600 may include a chemical addition system, which may be used for topping up coolant or other chemicals in the system. For example, based on monitored data and/or operator input, the chemical addition system may add water, propylene glycol, one or more additives, and/or other chemicals to the coolant loop. Accordingly, the chemical addition system may include one or more chemical injection pumps and/or equipment for adding chemicals to the coolant loop.

In some embodiments, the system 200, 300, 600 may include and/or be used with portable troubleshooting equipment. Such troubleshooting equipment may include additional sensors, filtration devices, ion exchange, ultraviolet (UV) for microbiology reduction, or other equipment. The troubleshooting equipment may be coupled to ports on the CDU 104, the liquid monitoring system 202, the coolant blade 302, and/or other components of the system 200, 300, 600.

In some embodiments, the system 200, 300, 600 may include improved filtering systems, which may add redundancy and high efficiency removal.

In some embodiments, the system 200, 300, 600, including the CDU 104, the liquid monitoring system 202, and/or the coolant blade 302, may include one or more features that provide service and/or operational improvements. In some embodiments, the system 200, 300, 600 may include hot-swappable capabilities for all critical items, such as sensors 210, 310, filters, pumps, and/or other components. For example, with hot-swap capability, a sensor 210, 310 may be removed and replaced with a replacement sensor 210, 310 while the monitoring system 200, 300, 600 remains active, and without interrupting cooling to the blade enclosure 102. Similarly, in some embodiments, the system 200, 300, 600 may include one or more valves and/or quick connects for clean in-place servicing, troubleshooting equipment, or start-up needs.

In some embodiments, the system 200, 300, 600 may include a hot-swappable heat exchanger. For example, one or more heat exchangers 140 included in the CDU 104 may be replaced without interrupting operation of the CDU 104 or other components of the system 200, 300, 600.

In some embodiments, the system 200, 300, 600 may incorporate complete drainability. That is, in an embodiment, the system 200, 300, 600 may be drained such that there is no fluid remaining in the coolant loop 108, 208, the conduit 204, 412, and/or other parts of the system 200, 300, 600 after draining.

In some embodiments, the system 200, 300, 600 may include a sanitary sample port. In some embodiments, the system 200, 300, 600 may include integrated chemical dosing. In some embodiments, the system 200, 300, 600 may include one or more devices to remove air entrained in the system.

In some embodiments, the system 200, 300, 600 may include a buffering tank for emergency cooling.

In some embodiments, the system 200, 300, 600 may include one or more modularity features for the CDU 104. For example, in some embodiments, the pumping and coolant delivery functions of the CDU 104 may be separated from the monitoring, filtration, and maintenance components of the CDU 104. Accordingly, those components may be isolated for service without stopping the coolant flow.

In some embodiments, the system 200, 300, 600 may include additional equipment to provide improved servicing. In some embodiments, the system 200, 300, 600 may include or otherwise be used with a fluid transfer cart for “transfusion” of additional fluids. For example, the fluid transfer cart may be attached to the system 200, 300, 600 to perform chemical top ups or other additions.

In some embodiments, the system 200, 300, 600 may include or otherwise be used with a water preparation cart, which may be embodied as a mobile water pretreatment device that delivers a specified water quality appropriate for the application (e.g., reverse osmosis, ion exchange, filtration, or other water pretreatment). The water preparation cart may be attached to the system 200, 300, 600, for example, when filling the coolant loop with water or when replacing coolant water.

In some embodiments, the system 200, 300, 600 may include or otherwise be used with a glycol cart, which may be embodied as a device that performs final filtration and quality check(s) before the propylene glycol (or other coolant chemical) is added to the system 200, 300, 600 from the bulk container storing the chemical.

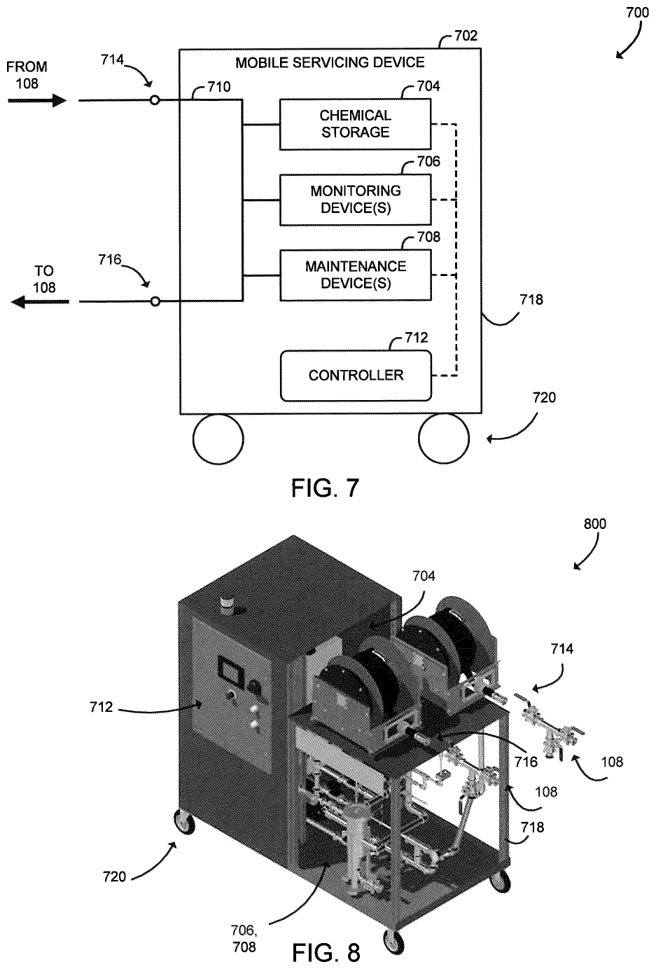

Referring now to FIG. 7, diagram 700 illustrates a mobile servicing device 702. The mobile servicing device 702 may be embodied as a fluid transfer cart, a water preparation cart, a glycol cart, or other movable equipment capable of connecting to an industrial water system, such as a secondary coolant loop, and performing maintenance and/or commissioning activities. As shown, in the illustrative embodiment, the mobile servicing device 702 includes chemical storage 704, one or more monitoring devices 706, and one or more maintenance devices 706. In other embodiments, the mobile servicing device 702 may include different combinations and/or arrangements of chemical storage 704, monitoring devices 706, and/or maintenance devices 706. It should be understood that in some embodiments, the mobile servicing device 702 may include one or more pumps (e.g., water pumps, chemical injection pumps, or other pumps), valves (e.g., solenoid valves, manually operated valves, etc.), and/or other fluid handling equipment. In certain embodiments, the mobile servicing device 702 may be used for adding additional chemical, such as any additive disclosed herein, to the coolant.

The chemical storage 704 may include one or more tanks, totes, bottles, bins, vessels, bulk containers, or other containers for storing one or more chemicals (including, in some embodiments, water) for introduction into an attached industrial water system. For example, the chemical storage 704 may store a glycol (e.g., propylene glycol), water, or a mixture thereof. As another example, the chemical storage 704 may store one or more additives for introduction into a coolant loop or other industrial water system, such as a corrosion inhibitor, a scale inhibitor, a buffer, a dispersant, a biocide, a scouring agent, a viscosity modifier, a heat transfer additive, a surfactant, a glycol, a fluorescent compound, a biostatic additive, copper, silver, a cleaning agent, water, and any combination thereof.

The monitoring devices 706 may be embodied as one or more sensors or other devices for monitoring the quality and/or other parameters of the attached industrial water system. For example, the monitoring devices 706 may include one or more sensors similar to the sensors 210 of the liquid monitoring system, including any electronic sensor capable of monitoring or otherwise measuring one or more parameters of the coolant, such as turbidity, pH, percentage propylene glycol, conductivity, fluorescence, color, dissolved oxygen content, flow rate, pressure, microbiology sensing, oxidation-reduction potential (ORP), inhibitor residuals, or other parameters.

The maintenance devices 708 may be embodied as any device capable of improving quality of liquid in the attached industrial water system or otherwise performing maintenance tasks for the industrial water system. For example, the maintenance devices 708 may include one or more filters capable of removing organic inorganic particles or other causes of fouling from liquid coolant, including in some embodiments one or more entrained air filters capable of removing air and/or other gases from the liquid coolant. As another example, the maintenance devices 708 may include one or more ion exchange devices or other devices capable of conditioning water. As another example, the maintenance devices 708 may include one or more devices capable of reducing biological activity in the liquid water system, such as one or more UV emitters. As another example, the maintenance devices 708 may include one or more ultrasound devices or other devices capable of mechanically removing fouling from the industrial water system.

As shown, the chemical storage 704, the monitoring devices 706, and the maintenance devices 706 may be communicatively coupled to a controller 712. The illustrative controller 712 may be the same as or similar to the controllers 212, 312 of FIGS. 2 and 3, as described above, and thus may include similar components. Accordingly, to improve clarity of this disclosure, those descriptions are not repeated herein.

The illustrative controller 712 may be configured to receive sensor data and other monitoring data from the monitoring devices 706. Additionally, the controller 712 may be configured to send commands to the chemical storage 704, for example to activate one or more chemical injection pumps or otherwise cause the chemical storage 704 to add associated chemicals to the connected industrial water system. Similarly, the controller 712 may be configured to send commands to the maintenance devices 708 to activate or deactivate maintenance operations. (Although illustrated as being performed by the chemical storage 704, it should be understood that in some embodiments chemical injection pumps or other components to add chemicals to the industrial water system may be included in the maintenance devices 708.) The controller 712 may send commands in response to monitoring data received from the monitoring devices 706. For example, the controller 712 may activate or deactivate maintenance devices 708 when a particular monitored parameter of the liquid coolant exceeds or falls beneath a predetermined threshold. Thresholds and associated operations may be configured by an operator of the device 702. In some embodiments, the controller 712 may send commands in response to user input, which may be performed by an operator of the device 702, a remote device, or otherwise provided to the controller 712. Further, the controller 712 may send commands to one or more solenoid valves, pumps, and/or other fluid handling equipment of the mobile servicing device 702 in order to perform the functions described herein.

As shown, the mobile servicing device 702 includes an inlet 714 and an outlet 716, which may be coupled to an industrial water system, such as the secondary coolant loop 108 of FIGS. 1-6. The inlet 714 and the outlet 716 are connected by a liquid conduit 710, which is fluidly connected to the chemical storage 704, the monitoring devices 706, and the maintenance devices 708. Each of the inlet 714 and the outlet 716 may include one or more quick connectors, valves, and other connectors to enable a fluid connection with the industrial water system. In some embodiments, both or one of the inlet 714 and/or outlet 716 may be connected to the industrial water system. For example, in an embodiment, the inlet 714 and the outlet 716 may be coupled to the secondary coolant loop 108 such that all of the coolant in the coolant loop 108 flows through the conduit 710 of the mobile servicing device 702 (i.e., a “series” connection). As another example, the inlet 714 and the outlet 716 may be coupled to the secondary coolant loop 108 such that the conduit 710 forms a side stream to the secondary coolant loop 108 and only part of the coolant flows through the conduit 710. In such embodiments, the secondary coolant loop 108 has a relatively small volume of coolant, and thus over time, all or substantially all of the coolant within the secondary loop 108 passes through the mobile servicing device 108. As yet another example, in an embodiment, only the outlet 716 may be connected to the secondary coolant loop 108, such as when initially filling the coolant loop 108 with liquid coolant. Of course, other arrangements and connections are possible.

As described above, the mobile servicing device 702 includes movable equipment, and thus may be moved between, connected to, and disconnected from multiple different industrial water systems. Accordingly, the mobile servicing device 702 includes a structural frame 718 and one or more mobility features 720, which are illustratively wheels. The structural frame 718 supports and integrates the components of the mobile servicing device 702, allowing it to be moved as a single unit. The mobility features 720 support movement of the device 702. The illustrative device 702 may be moved manually by one or more operators. Additionally or alternatively, the mobile servicing device 702 may include one or more traction motors and/or other powered mobility features. Of course, in some embodiments, the mobile servicing device 702 may lack mobility features 720, may be attached or anchored to a fixed structure and/or surface, or may be otherwise fixed in position permanently and/or temporarily.

Further, in the illustrative embodiment shown in FIG. 7, the chemical storage unit 704, the monitoring device(s) 706, and the maintenance device(s) are integrated with the mobile servicing cart 702, for example by being attached to the structural frame 718. Additionally or alternatively, it should be understood that in some embodiments, one or more of those components may be external to the mobile servicing cart. For example, in an embodiment, the mobile service cart 702 may be fluidly coupled to one or more external storage tanks or other external chemical storage units 704.

Referring now to FIG. 8, diagram 800 illustrates one example embodiment of a mobile servicing device 702, which is illustratively a moveable glycol cart with wheels 720, which is manually moveable. As shown, the cart 702 includes chemical storage 704, monitoring devices 706, maintenance devices 708, and a controller 712. The controller 712 includes an operator-accessible display screen and one or more controls. The inlet 714 and the outlet 716 are embodied as hoses with quick-connect features, which may connect to one or more valves coupled to the secondary coolant loop 108. Each of the inlet 714 and the outlet 716 includes a corresponding spool of hose, allowing an operator to make connections at a distance from the frame 718 of the cart 702.

As an illustrative example, in an embodiment the mobile service cart 702 may be a glycol cart configured for use with a direct-to-chip (DTC) cooling system. As part of an installation or commissioning operation, each asset of the DTC cooling system may be connected to the service cart 702, including a blade enclosure 102 and individual compute blades 120. For example, glycol chemical hoses may be connected from the service cart 702 to a rack (e.g., enclosure 102) or to a compute blade 120. A reject line from the servicing cart 702 may be connected with a glycol chemical hose to an appropriate storage container. The service cart 702 may be connected to an appropriate electrical power source or other power source (e.g., 120/230 VAC 15/6.0 AMP single phase electrical service or other power supply). In an embodiment, chemical storage 704 of the service cart 702 may be filled with appropriate chemicals, such as cleaning solution, a glycol, or any additive disclosed herein.

In response to a command from an operator or other starting condition, the service cart 702 starts operating in a flush or cleaning mode. In the cleaning mode, glycol, an additive, and/or cleaning solution is recirculated throughout the attached asset (e.g., the compute blade 120, the blade enclosure 102, the CDU 140, and/or other attached equipment). While the liquid is recirculated throughout the asset, the service cart 702 monitors one or more parameters of the liquid, such as turbidity, particle size, volume transferred, or other parameters. Additionally, while the liquid is recirculated, one or more filters or other maintenance devices 706 of the service device 702 may clean the liquid. The cleaning mode may continue until the monitored parameter reaches an acceptable value or other predetermined threshold. For example, the cleaning mode may continue until measured turbidity drops below a predetermined threshold. As another example, the cleaning mode may continue until a predetermined volume of liquid has passed through the service device 702 (e.g., three times the volume of the attached asset or other threshold).

After completing the cleaning mode, the service cart 702 may be prepared for filling mode. For example, the service cart 702 may be filled with fresh glycol coolant or otherwise connected to a glycol tank. In some embodiments, a service cart 702 configured for cleaning or flushing may be disconnected from the asset, and another service cart 702 configured for filling may be attached to the asset.

In response to a command from the operator or other starting condition, the service cart 702 starts operating in a filling mode. In the filling mode, the service cart 702 pumps fresh glycol coolant (e.g., new, virgin, or otherwise high-quality liquid glycol coolant) into the attached asset. The service cart 702 may reject or recover glycol coolant returned from the asset. While the asset is being filled, the service cart 702 monitors one or more parameters of the liquid coolant (e.g., the liquid coolant returned from the asset). The monitored assets may include, for example, turbidity, percent glycol by weight or other percent glycol, particle size, or other parameters. Filling may continue until the monitored parameter reaches an acceptable value or other predetermined threshold. For example, filling may continue until the percent by weight glycol of liquid recovered from the asset matches the expected percent by weight glycol of new glycol coolant.

After completing the filling mode, any glycol rejection line may be closed, and the filling process may be verified. For example, one or more digital or physical certificates of verification may be generated as described further below. After completing the filling mode and certifying the fill, the asset (e.g., the blade enclosure 102, the compute blade 120, the CDU 140, or other asset) may be installed or attached to the secondary coolant loop 108 or otherwise commissioned for use.

In addition to performing initial commissioning when a component of the DTC cooling system is initially installed, it should be understood that the service cart 702 may be used to perform similar operations for ongoing maintenance, repair, and expansion. For example, a similar flush and fill process may be performed when cleaning and re-installing a compute blade 120 into an existing system, when installing a compute blade 120 as a replacement for a faulty blade, when installing an additional compute blade 120 and/or enclosure 102 into an existing system, or when performing other maintenance or service operations. Accordingly, the illustrated service device 702 and methods may clean and validate the quality of liquid coolant in an asset (e.g., a rack, blade, CDU, or other equipment) prior to that asset being attached to the secondary coolant loop 108. Accordingly, the disclosed devices and methods may reduce contaminants introduced into the DTC cooling system, which leads to better cooling performance and may extend the life of the liquid coolant and the asset.

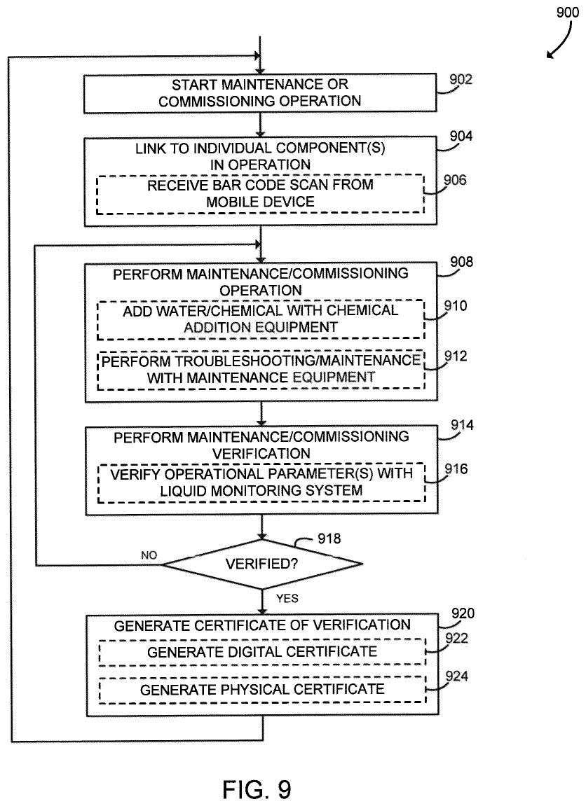

In some embodiments, the system 200, 300, 600 may include one or more maintenance system and process improvements. In some embodiments, full-service commissioning verification may be performed per part for the system 200, 300, 600. For example, in some embodiments, the system 200, 300, 600 may allow the customer to verify that the appropriate steps have been taken before delivery to ensure a clean and functional part. This may be part of an overall quality system that uses standard operating procedures and is linked to an individual component via some identifying element (e.g., a bar code). For example, the system may perform one or more commissioning operations with verification as described further below in connection with the method of FIG. 9. Continuing that example, the verification system may be provided to the customer via a remote device 220, 320 or other maintenance portal.

In some embodiments, the system 200, 300, 600 may provide a service application that allows a field representative or other servicer to scan a barcode on a probe, perform the recommended service, and document completion of the service. Continuing that example, the application may be set up to schedule time-based or performance-based service checks. The service application may be executed, for example, by a mobile computing device, which may be in communication with the controller 212, 312 and/or the remote device 220, 320.

In some embodiments, the system 200, 300, 600 may provide additional maintenance operations and/or other capabilities. Those maintenance operations may be performed automatically, for example, in response to monitoring data and/or may be performed in response to operator commands. In some embodiments, the system 200, 300, 600 may provide an ability to reverse the flow of the coolant, which may keep cold plates or other components from clogging and/or may be used as a remediation step if fouling is suspected. In some embodiments, the system 200, 300, 600 may reduce touchpoints for servicers, for example, by providing automated or semiautomated sample collection.

Referring now to FIG. 9, in use, a method for performing a maintenance or commissioning operation may be performed in connection with any one of the systems 100, 200, 300, 600 and/or a mobile servicing device 702. It should be understood that, in some embodiments, one or more of the operations of the method 900 may be performed by a controller 212, 312, 712 and/or a remote device 220, 320 as shown in FIGS. 2-8. The method 900 begins in block 902, in which a maintenance or commissioning operation is started. For example, a maintenance operation may include coolant maintenance operations for an industrial water system, such as a direct-to-chip (DTC) cooling system. Such coolant maintenance operations may include filtering liquid coolant in the secondary coolant loop 108, chemically treating the liquid coolant, adding additional chemicals, such as propylene glycol, to the liquid coolant, mechanically or otherwise treating the liquid coolant, or otherwise performing maintenance operations on the liquid coolant. In some embodiments, the maintenance operation may include repairing, replacing, or other maintenance operations performed on a component of the system, such as a CDU 104, a heat exchanger 104, a liquid monitoring system 202, a coolant blade 302, a blade enclosure 102, a compute blade 120, or other component. In some embodiments, the maintenance operation may be performed, at least in part, by connecting a mobile servicing device 702 to a component of the system, such as a CDU 104, a heat exchanger 104, a liquid monitoring system 202, a coolant blade 302, a blade enclosure 102, a compute blade 120, or other component. In some embodiments, the maintenance operation may be performed, at least in part, by connecting a mobile servicing device 702 to the secondary coolant loop 108.

As another example, a commissioning operation may include installing new or replacement equipment in an industrial water system, such as a direct-to-chip (DTC) cooling system such as any one of the systems 100, 200, 300, 600. New equipment may include, for example, new or replacement CDUs 104 or components of CDUs 104 such as heat exchangers; new or replacement liquid monitoring systems 202 or coolant blades 302; new or replacement blade enclosures 102 or compute blades 120, or other any new or replacement equipment. In some embodiments, the commissioning operation may be performed, at least in part, by connecting a mobile servicing device 702 to a component of the system, such as a CDU 104, a heat exchanger 104, a liquid monitoring system 202, a coolant blade 302, a blade enclosure 102, a compute blade 120, or other component. The commissioning operation may include connecting the new or replacement equipment to the secondary coolant loop 108 and filling the coolant loop 108 with liquid coolant. Similar to the maintenance operation, the commissioning operation may be performed, at least in part, by connecting a mobile servicing device 702 to the secondary coolant loop 108.

In block 904, one or more individual component(s) involved in the maintenance or commissioning operation are linked to an electronic record of the operation. The electronic record may be maintained, for example, by one or more of the controllers 212, 312, 712 and/or by the remote device 220, 320. The components involved in the operation may include, for example, new or replacement components installed to the industrial water system and/or components that are repaired or otherwise maintained in the operation. In some embodiments, in block 906 a bar code scan associated with the individual component(s) may be received from an external device, such as a mobile computing device in communication with the controllers 212, 312, 712 and/or the remote device 220, 320. The bar code may identify the particular individual components with a serial number or other unique identifier, allowing for component life cycle tracking, among other operations.

In block 908, the maintenance or commissioning operation is performed. As described above, in some embodiments part or all of the operation may be performed using a mobile servicing device 702 coupled to the secondary coolant loop 108 or otherwise coupled to the industrial water system. In some embodiments, in block 910 water or a chemical may be added to the secondary coolant loop 108 using chemical addition equipment. For example, in an embodiment additional propylene glycol may be added to the secondary coolant loop 108 replace propylene glycol that has been lost or otherwise degraded. As another example, one or more chemical additives such as one or more biocides or biostatic additives, surfactants, heat transfer promoters, scouring agents, cleaning agents, acids, bases, or other additives. In some embodiments, in block 912, one or more troubleshooting or maintenance operations may be performed. In some embodiments, those operations may be performed using a mobile servicing device 702 coupled to the secondary coolant loop 108 or otherwise coupled to the industrial water system. As described above, maintenance operations may include filtering or otherwise treating the liquid coolant and/or repairing, replacing, or other maintenance operations performed on a component of the system. As another example, troubleshooting or maintenance operations may include measuring one or more parameters of the system, for example using one or more of the liquid monitoring system 202, the coolant blade 302, and/or the monitoring devices 706 of the mobile servicing device 702.

In block 914, maintenance or commissioning verification is performed. This verification may include any determination that the maintenance or commissioning operation has been successfully completed. For example, in some embodiments an operator may indicate that the operation has been completed using a user interface of the controller 212, 312, 712 or other user interface. Additionally or alternatively, the operation may be verified using sensor data or other available diagnostic data. In some embodiments, in block 916 one or more operational parameters may be verified using the liquid monitoring system 202, the coolant blade 302, the monitoring devices 706, or other liquid monitoring sensors or other devices. For example, in an embodiment, the current concentration of propylene glycol in the secondary coolant loop 108 may be measured and compared to one or more thresholds or other target values.

In block 918, it is determined whether the maintenance or commissioning operation was successfully verified. If not, the method 900 loops back to block 908, in which performance of the maintenance or commissioning operation continues. If successfully verified, the method 900 advances to block 920.

In block 920, a certificate of verification is generated. The certificate of verification may be embodied as any record, data, or other output indicating that the maintenance or commissioning operation was successfully verified. In some embodiments, the certificate of verification may be cryptographically signed or otherwise signed such that the certificate can be authenticated, attested, or otherwise objectively verified. In some embodiments, the certificate may be linked to the individual components involved in the operation. For example, in some embodiments the certificate may attest or otherwise verify the serial number or other unique identifiers determined as described above in block 904. The certificate of verification may be embodied in one or more formats, and in some embodiments may be verified by an in-person operator or by a remote user. In some embodiments, in block 922, the certificate of verification may be generated as a digital certificate. The digital certificate may be stored, for example, by the controller 212, 312, 712 and/or by the remote device 220, 320. In some embodiments, the digital certificate may be stored digitally with the verified equipment, for example on a radio frequency identifier (RFID) tag or other embedded tag included in the industrial water system. In some embodiments, in block 924 a physical certificate may be generated. The physical certificate may be embodied as, for example, a physical bar code representing the digital certificate or other digital identifier. In an embodiment, this physical bar code may be attached to the physical equipment that was maintained and/or commissioned. Continuing that example, operators may authenticate or attest the certificate of verification by, for example, scanning the bar code that was attached to the physical equipment. After generating the certificate of verification, the method 900 loops back to block 902, in which additional maintenance or commissioning operations may be performed.

In some embodiments, the system 200, 300, 600 may include coolant features that improve cooling performance and efficiency. In some embodiments, the coolant may include one or more features for improved performance, durability, maintenance, and/or efficiency. In some embodiments, the coolant may include one or more biostatic additives. In some embodiments, the coolant may include one or more heat transfer additives. In some embodiments, the coolant may include copper or silver as a microbial treatment. In some embodiments, the coolant may include aluminum, aluminum oxide, graphite, and/or other carbon-based nanoparticles.

In some embodiments, the coolant may include a cleaning additive, such as a scouring agent. The cleaning agent may be used as needed and then filtered out of the cooling loop.

All of the compositions and methods disclosed and claimed herein can be made and executed without undue experimentation in light of the present disclosure. While this invention may be embodied in many different forms, there are described in detail herein specific preferred embodiments of the invention. The present disclosure is an exemplification of the principles of the invention and is not intended to limit the invention to the particular embodiments illustrated. In addition, unless expressly stated to the contrary, use of the term “a” is intended to include “at least one” or “one or more.” For example, “a glycol” is intended to include “at least one glycol” or “one or more glycols.”

Any ranges given either in absolute terms or in approximate terms are intended to encompass both, and any definitions used herein are intended to be clarifying and not limiting. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all subranges (including all fractional and whole values) subsumed therein.

Any composition disclosed herein may comprise, consist of, or consist essentially of any element, component and/or ingredient disclosed herein or any combination of two or more of the elements, components or ingredients disclosed herein.

Any method disclosed herein may comprise, consist of, or consist essentially of any method step disclosed herein or any combination of two or more of the method steps disclosed herein.

The transitional phrase “comprising,” which is synonymous with “including,” “containing,” or “characterized by,” is inclusive or open-ended and does not exclude additional, un-recited elements, components, ingredients and/or method steps.

The transitional phrase “consisting of” excludes any element, component, ingredient, and/or method step not specified in the claim.

The transitional phrase “consisting essentially of” limits the scope of a claim to the specified elements, components, ingredients and/or steps, as well as those that do not materially affect the basic and novel characteristic(s) of the claimed invention.

Furthermore, the invention encompasses any and all possible combinations of some or all of the various embodiments described herein. It should also be understood that various changes and modifications to the presently preferred embodiments described herein will be apparent to those skilled in the art. Such changes and modifications can be made without departing from the spirit and scope of the invention and without diminishing its intended advantages. It is therefore intended that such changes and modifications be covered by the appended claims.

What is claimed is:

1. A device for industrial water system servicing, the device comprising:
a structural frame coupled to a mobility feature;
an inlet and an outlet coupled to a fluid conduit, wherein the inlet and the outlet are configured to removably couple to a component of an industrial water system;
a chemical storage unit fluidly coupled to the fluid conduit, wherein the chemical storage unit is configured to supply an additive to the fluid conduit when the inlet or the outlet is coupled to the component of the industrial water system; and
a maintenance device coupled to the structural frame and fluidly coupled to the fluid conduit, wherein the maintenance device is configured to perform an operation on a liquid from the fluid conduit when the inlet or the outlet is coupled to the component of the industrial water system.

2. The device of claim 1, wherein the industrial water system comprises a secondary coolant loop for a direct-to-chip cooling system.

3. The device of claim 1, wherein the component of the industrial water system comprises a compute blade, a blade enclosure, or a cooling distribution unit (CDU).

4. The device of claim 1, wherein the chemical storage unit is coupled to the structural frame.

5. The device of claim 1, wherein the additive is selected from the group consisting of a corrosion inhibitor, a scale inhibitor, a buffer, a dispersant, a biocide, a scouring agent, a viscosity modifier, a heat transfer additive, a surfactant, a glycol, a fluorescent compound, a biostatic additive, copper, silver, a cleaning agent, water, and any combination thereof.

6. The device of claim 1, wherein the maintenance device comprises a filter, an ion exchange device, an ultraviolet light emitter, an ultrasound device, or any combination thereof.

7. The device of claim 1, further comprising:
a measurement device coupled to the structural frame and fluidly coupled to the fluid conduit, wherein the measurement device is configured to generate data indicative of a property of the liquid within the fluid conduit; and
a controller coupled to the structural frame and operatively coupled to the measurement device, wherein the controller is configured to receive the data from the measurement device.

8. The device of claim 7, wherein the measurement device comprises a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, a microbiology sensor, an oxidation-reduction potential sensor, a device for measuring organic and/or inorganic fouling, a refractometer, or any combination thereof.

9. A method for servicing a direct computing cooling system, the method comprising:
fluidly connecting a service device to an asset of the direct computing cooling system;
circulating, by the service device, a cleaning fluid within the asset until a first measured parameter of liquid coolant of the asset reaches a first predetermined threshold; and
in response to the first measured parameter reaching the first predetermined threshold, filling, by the service device, the asset with additional liquid coolant until a second measured parameter of the liquid coolant reaches a second predetermined threshold.

10. The method of claim 9, further comprising attaching the asset to a secondary coolant loop of the direct computing cooling system in response to the second measured parameter reaching the second predetermined threshold.

11. The method of claim 9, wherein the asset comprises a compute blade, a blade enclosure, a cooling distribution unit, or the secondary cooling loop.

12. The method of claim 9, wherein the first measured parameter comprises turbidity and the second measured parameter comprises turbidity, glycol wt. %, pH, conductivity, temperature, flow rate, fluorescence, color, dissolved oxygen, pressure, differential pressure, vibration, IR light, alkalinity, entrained air, particle size, microbiology, oxidation-reduction potential, organic fouling, inorganic fouling, or index of refraction.

13. The method of claim 9, further comprising measuring, by the service device, the first measured parameter and the second measured parameter of the liquid coolant with a measurement device of the service device, optionally wherein the measurement device comprises a conductivity sensor, a turbidity sensor, a pH sensor, a temperature sensor, a flow rate sensor, a fluorometer, a color sensor, a dissolved oxygen sensor, a pressure sensor, a differential pressure sensor, a vibration sensor, an IR light sensor, an alkalinity sensor, an entrained air sensor, a particle size sensor, a sensor for measuring glycol wt. %, a microbiology sensor, an oxidation-reduction potential sensor, a device for measuring organic and/or inorganic fouling, a refractometer, or any combination thereof.

14. The method of claim 9, further comprising:
coupling a reject line of the service device to a storage container, wherein returned liquid coolant from the asset is stored in the storage container while filling the asset; and
closing, by the service device, the reject line in response to the second measured parameter reaching the second predetermined threshold.

15. The method of claim 9, wherein circulating the cleaning fluid within the asset further comprises filtering the liquid coolant by a filter device of the service device and/or adding, by the service device, a cleaning solution, water, glycol, or a water solution with cleaning or treatment chemistry to the liquid coolant.

16. The method of claim 9, further comprising generating, by the service device, a certificate of verification in response to the second measured parameter reaching the second predetermined threshold.

17. The method of claim 16, further comprising generating, by the service device, a physical representation of the certificate of verification and optionally attaching the physical representation of the certificate of verification to the asset.

18. A method for management of an industrial water system, the method comprising:
linking, by a controller, a first component of an industrial water system to a maintenance operation performed with the maintenance operation;
verifying, by the controller, performance of the maintenance operation; and
generating, by the controller, a certificate of verification in response to verifying the performance of the maintenance operation, wherein the certificate of verification is indicative of the first component and the maintenance operation.

19. The method of claim 18, further comprising:
attaching a mobile servicing device to the industrial water system; and
performing the maintenance operation with the mobile servicing device after attaching the mobile servicing device to the industrial water system.

20. The method of claim 18, wherein verifying the performance of the maintenance operation comprises:
measuring, by the controller with a liquid monitoring system, a property of a liquid in the industrial water system; and
comparing, by the controller, the property to a predetermined threshold.
